(19) United States
(12) Patent Application Publication
(10) Pub. No.: US 2025/0062123 A1
(43) Pub. Date: Feb. 20, 2025

(54) TREATMENTS FOR THIN FILMS USED IN PHOTOLITHOGRAPHY

(71) Applicant: Applied Materials, Inc., Santa Clara, CA (US)

(72) Inventors: SHASHANK SHARMA, Sunnyvale, CA (US); KAI B. NG, Santa Clara, CA (US); NORMAN TAM, Cupertino, CA (US); YUQI GUO, Sunnyvale, CA (US); ANDY LO, San jose, CA (US); HUIXIONG DAI, San jose, CA (US); KHOI PHAN, San jose, CA (US); CHIHAN HSU, Milpitas, CA (US); MADHUR SACHAN, Belmont, CA (US); NASRIN KAZEM, Santa Clara, CA (US); ZHENXING HAN, Sunnyvale, CA (US)

(21) Appl. No.: 18/235,249

(22) Filed: Aug. 17, 2023

(51) Int. Cl. H01L 21/027; H01L 21/308; H01L 21/311; H01L 21/3213

(52) U.S. Cl. CPC H01L 21/0274; H01L 21/3081; H01L 21/3086; H01L 21/3088; H01L 21/31144; H01L 21/32139

(57) ABSTRACT

Embodiments disclosed herein include a method of thermal treatment or radical species treatment of a photoresist a metal-oxide photoresist. In an embodiment, a method of patterning a metal-oxide photoresist, such as a Sn-based photoresist, includes depositing the metal-oxide photoresist over a substrate, exposing the metal-oxide photoresist with an extreme ultra-violet (EUV) exposure to form exposed regions and non-exposed regions, developing the exposed metal-oxide photoresist, and performing a thermal treatment and/or a radical species treatment of the metal-oxide photoresist.

### BACKGROUND

### 1) Field

Embodiments of the present disclosure pertain to the field of semiconductor processing and, in particular, to methods of performing thermal treatments or radical species treatments for photo-resist related stacks.

### 2) Description of Related Art

Lithography has been used in the semiconductor industry for decades for creating 2D and 3D patterns in microelectronic devices. The lithography process involves spin-on deposition of a film (photoresist), irradiation of the film with a selected pattern by an energy source (exposure), and removal (etch) of exposed (positive tone) or non-exposed (negative tone) region of the film by dissolving in a solvent. A bake will be carried out to drive off remaining solvent.

The photoresist should be a radiation sensitive material and upon irradiation a chemical transformation occurs in the exposed part of the film which enables a change in solubility between exposed and non-exposed regions. Using this solubility change, either exposed or non-exposed regions of the photoresist is removed (etched). The photoresist is then developed and the pattern can be transferred to the underlying thin film or substrate by etching. After the pattern is transferred, the residual photoresist is removed and repeating this process many times can give 2D and 3D structures to be used in microelectronic devices. It is to be appreciated that a photoresist can be associated with underlayers and/or hardmasks to provide a photoresist stack.

Several properties are important in lithography processes. Such important properties include sensitivity, resolution, lower line-edge roughness (LER), etch resistance, and ability to form thinner layers. When the sensitivity is higher, the energy required to change the solubility of the as-deposited film is lower. This enables higher efficiency in the lithographic process. Resolution and LER determine how narrow features can be achieved by the lithographic process. Higher etch resistant materials are required for pattern transferring to form deep structures. Higher etch resistant materials also enable thinner films. Thinner films increase the efficiency of the lithographic process.

### SUMMARY

Embodiments disclosed herein include a method of patterning a photoresist using a thermal treatment or radical species treatment process. In an embodiment, a method includes depositing the metal-oxide photoresist over a substrate, exposing the metal-oxide photoresist with an extreme ultra-violet (EUV) exposure to form exposed regions and non-exposed regions, developing the exposed metal-oxide photoresist, and performing a thermal treatment of the metal-oxide photoresist.

In an embodiment, another method includes depositing the photoresist over a substrate, exposing the metal-oxide photoresist with an extreme ultra-violet (EUV) exposure to form exposed regions and non-exposed regions, developing the exposed metal-oxide photoresist, and performing a radical species treatment of the metal-oxide photoresist.

Embodiments may further include a method that includes depositing the photoresist over a substrate, exposing the metal-oxide photoresist with an extreme ultra-violet (EUV) exposure to form exposed regions and non-exposed regions, developing the exposed metal-oxide photoresist, and performing thermal treatment and/or a radical species treatment of the metal-oxide photoresist.

### BRIEF DESCRIPTION OF THE DRAWINGS

FIG. 1 illustrates cross-sectional views representing various operations in a patterning process using a positive tone photo-resist material formed by processes described herein, in accordance with an embodiment of the present disclosure.

FIG. 2 illustrates cross-sectional views representing various operations in a patterning process using a negative tone photo-resist material formed by processes described herein, in accordance with an embodiment of the present disclosure.

FIG. 3 illustrates cross-sectional views representing various operations in a method of patterning a photo-resist layer, in accordance with an embodiment of the present disclosure.

FIG. 4 illustrates cross-sectional views representing various operations in a method of patterning a photo-resist layer, in accordance with an embodiment of the present disclosure.

FIG. 5 illustrates cross-sectional views representing various operations in a method of patterning a photo-resist layer, in accordance with an embodiment of the present disclosure.

FIG. 6 is a cross-sectional illustration of a processing tool that may be used to implement one or more processes described herein, in accordance with an embodiment of the present disclosure.

FIG. 7 is a cross-sectional illustration of a processing tool for depositing a positive or negative tone metal-oxide photoresist layer over a substrate and/or for performing treatment processes, in accordance with an embodiment of the present disclosure.

FIG. 8 illustrates a block diagram of an exemplary computer system, in accordance with an embodiment of the present disclosure.

### DETAILED DESCRIPTION

Methods of treating a positive or negative tone metal-oxide photoresist are described herein. In the following description, numerous specific details are set forth, such as chemical vapor deposition (CVD) and atomic layer deposition (ALD) processes and material regimes for depositing a positive or negative tone metal-oxide photoresist, in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

To provide context, photoresist systems used in extreme ultraviolet (EUV) lithography suffer from low efficiency. That is, existing photoresist material systems for EUV lithography require high dosages in order to provide the needed solubility switch that allows for developing the photoresist material. Traditionally, carbon based films called organic chemically amplified photoresists (CAR) have been used as a photoresist. However, more recently organic-inorganic hybrid materials (metal-oxo) have been used as a photoresist with extreme ultraviolet (EUV) radiation. Such materials typically include a metal (such as Sn, Hf, Zr), oxygen, and carbon. Transformation from deep UV (DUV) to EUV in the lithographic industry facilitated narrow features with high aspect ratio. Metal-oxo based organic-inorganic hybrid materials have been shown to exhibit lower line edge roughness (LER) and higher resolution which are required for forming narrow features. Also, such films have higher sensitivity and etch resistance properties and can be implemented to fabricate relatively thinner films.

Currently, organo-tin oxo compounds have entered the mainstream semiconductor industry process flow to mitigate the low absorbance of extreme ultraviolet (EUV) radiation by thin films of organic resists that lead to poor sensitivity and their inability to handle rigors of development and etching conditions. However, the respective lithography performance needs to attain better Line width roughness (LWR) indexes (LER is one of the most critical performance indexes to be improved for EUV Lithography) to enable high resolution patterning.

In accordance with one or more embodiments of the present disclosure, thermal and radical species treatments of EUV patterning films are described.

Embodiments include thermal and radical species treatment of films typically used in EUV patterning. Advantages for implementing embodiments described herein can include improving the patterning performance in terms of pattern transfer and defectivity. Embodiments can be implemented to improve EUV patterning by improving line edge roughness, line width roughness, defectivity, bridging, line breaks, pattern collapse, EUV dose scaling, and/or etch selectivity.

Current state of the art includes bakes on the lithography track system. These bakes only have temperature and time as tuning knobs available to modify the various films. Embodiments described herein can be implemented to provide ways of precisely modifying the films by either annealing them in specific ambients or treating them with specific radical species chemistries or combining the two processes on a high productivity platform to result in film properties that improve the overall patterning performance.

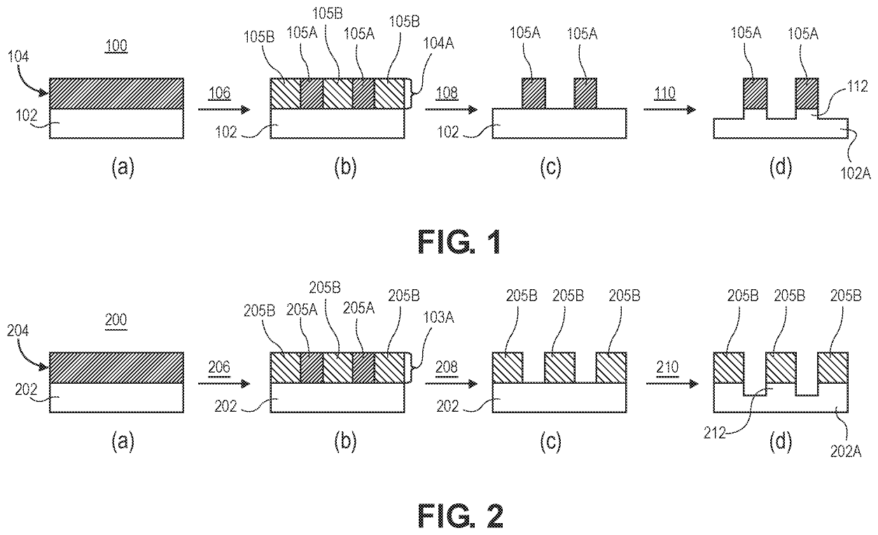

To provide further background, FIG. 1 illustrates cross-sectional views representing various operations in a patterning process using a positive tone photo-resists material formed by processes described herein, in accordance with an embodiment of the present disclosure.

Referring to part (a) of FIG. 1, a starting structure 100 includes a positive tone photoresist layer 104 above a substrate or underlying layer 102. In one embodiment, the positive tone photoresist layer 104 is deposited using dry or wet deposition. Referring to part (b) of FIG. 1, the starting structure 100 is irradiated 106 in select locations to form an irradiated photoresist layer 104A having irradiated regions 105B and non-irradiated regions 105A. Referring to part (c) of FIG. 1, a removal or etch process 108 is used to provide a developed photoresist layer of non-irradiated regions 105A. Referring to part (d) of FIG. 1, an etch process 110 using the non-irradiated regions 105A as a mask is used to pattern the substrate or underlying layer 102 to form patterned substrate or patterned underlying layer 102A including etched features 112.

Referring again to FIG. 1, the positive tone photoresist 104 is a radiation sensitive material and, upon irradiation, a chemical transformation occurs in the exposed part of the film which enables a change in solubility between exposed and non-exposed regions. Using the solubility change, exposed regions of the positive tone photoresist are removed (etched). The positive tone photoresist is then developed and the pattern can be transferred to the underlying thin film or substrate by etching. After the pattern is transferred, the residual positive tone photoresist is removed. The process can be repeated many times can fabricate 2D and 3D structures, e.g., for use in microelectronic devices.

To provide further background, FIG. 2 illustrates cross-sectional views representing various operations in a patterning process using a negative tone photo-resists material formed by processes described herein, in accordance with an embodiment of the present disclosure.

Referring to part (a) of FIG. 2, a starting structure 200 includes a negative tone photoresist layer 203 above a substrate or underlying layer 202. In one embodiment, the negative tone photoresist layer 203 is deposited using dry or wet deposition. Referring to part (b) of FIG. 2, the starting structure 200 is irradiated 206 in select locations to form an irradiated photoresist layer 203A having irradiated regions 205B and non-irradiated regions 205A. Referring to part (c) of FIG. 2, a removal or etch process 208 is used to provide a developed photoresist layer of irradiated regions 205B. Referring to part (d) of FIG. 2, an etch process 210 using the irradiated regions 205B as a mask is used to pattern the substrate or underlying layer 202 to form patterned substrate or patterned underlying layer 202A including etched features 212.

Referring again to FIG. 2, the negative tone photoresist 203 is a radiation sensitive material and, upon irradiation, a chemical transformation occurs in the exposed part of the film which enables a change in solubility between exposed and non-exposed regions. Using the solubility change, non-exposed regions of the negative tone photoresist are removed (etched). The negative tone photoresist is then developed and the pattern can be transferred to the underlying thin film or substrate by etching. After the pattern is transferred, the residual negative tone photoresist is removed. The process can be repeated many times can fabricate 2D and 3D structures, e.g., for use in microelectronic devices.

The positive tone resist and the negative tone resist may both be metal-oxide photoresist films. In some instances the same material system may be used for the both the positive tone resist and the negative tone resist. That is, dry or wet deposition with an EUV exposure may be used to form either positive tone or negative tone resists.

As described above, thermal treatments or radical species treatments can be performed for metal-oxide photoresists.

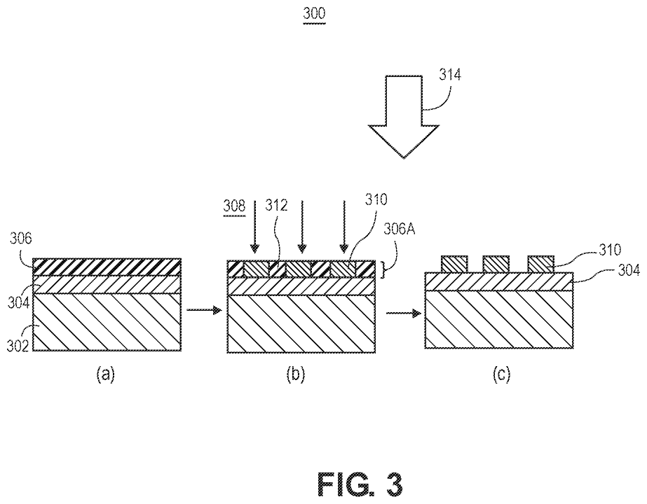

As a first exemplary process flow, FIG. 3 illustrates cross-sectional views representing various operations in a method of patterning a photo-resist layer, in accordance with an embodiment of the present disclosure.

Referring to FIG. 3, a method 300 of patterning a metal-oxide photoresist, such as a Sn-based photoresist, includes (a) depositing the metal-oxide photoresist 306 over a substrate 302 (with optional underlayer(s) and/or hardmask(s) 304 there between). In one embodiment, the underlayer(s) and/or hardmask(s) 304 are one or more layers such as a spin-on or CVD SiOC layer, a spin-on CVD carbon layer, a CVD amorphous silicon layer, a CVD SiON layer, and/or a spin-on or CVD or ALD metal oxide layer. In one embodiment, the photoresist 306 is a spin-on organic resist, a spin on metal oxide resist, or a CVD metal oxide resist.

The method also includes (b) exposing the metal-oxide photoresist with an extreme ultra-violet (EUV) exposure 308 to form exposed regions 310 and non-exposed regions 312. The method also includes (c) developing the exposed metal-oxide photoresist 306A. It is to be appreciated that the remaining mask (e.g., exposed regions 310) can be used as an etch mask to pattern underlying layers.

Referring again to FIG. 3, in accordance with an embodiment of the present disclosure, a thermal treatment 314 of the metal-oxide photoresist is performed. In one such embodiment, the thermal treatment 314 is performed at one or more of the following stages: (a) following deposition but prior to exposure, (b) following exposure but prior to development, and/or (c) following development and prior to using the developed photoresist as an etch mask. Regarding (b), in one embodiment, the thermal treatment 314 is performed prior to or following a post-exposure bake. In an embodiment, the thermal treatment 314 is performed at temperature in the range of 60-400 degrees Celsius, at a pressure of 1 Torr to 760 Torr, and for a duration in the range of 10 seconds to 10 minutes.

In an embodiment, the metal-oxide photoresist 306 is a positive tone photoresist. In another embodiment, the metal-oxide photoresist 306 is a negative tone photoresist. In an embodiment, developing the exposed metal-oxide photoresist 306A includes removing the non-exposed regions 312, as is depicted. In another embodiment, however, developing the exposed metal-oxide photoresist 306A includes removing the exposed regions 310.

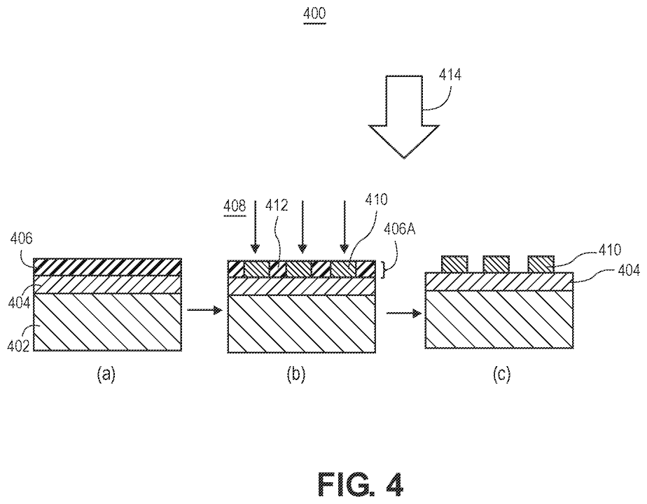

As a second exemplary process flow, FIG. 4 illustrates cross-sectional views representing various operations in a method of patterning a photo-resist layer, in accordance with an embodiment of the present disclosure.

Referring to FIG. 4, a method 400 of patterning a metal-oxide photoresist, such as a Sn-based photoresist, includes (a) depositing the metal-oxide photoresist 406 over a substrate 402 (with optional underlayer(s) and/or hardmask(s) 404 there between). In one embodiment, the underlayer(s) and/or hardmask(s) 404 are one or more layers such as a spin-on or CVD SiOC layer, a spin-on CVD carbon layer, a CVD amorphous silicon layer, a CVD SiON layer, and/or a spin-on or CVD or ALD metal oxide layer. In one embodiment, the photoresist 406 is a spin-on organic resist, a spin on metal oxide resist, or a CVD metal oxide resist.

The method also includes (b) exposing the metal-oxide photoresist with an extreme ultra-violet (EUV) exposure 408 to form exposed regions 410 and non-exposed regions 412. The method also includes (c) developing the exposed metal-oxide photoresist 406A. It is to be appreciated that the remaining mask (e.g., exposed regions 410) can be used as an etch mask to pattern underlying layers.

Referring again to FIG. 4, in accordance with an embodiment of the present disclosure, a radical species treatment 414 of the metal-oxide photoresist is performed. In one such embodiment, the radical species treatment 414 is performed at one or more of the following stages: (a) following deposition but prior to exposure, (b) following exposure but prior to development, and/or (c) following development and prior to using the developed photoresist as an etch mask. Regarding (b), in one embodiment, the radical species treatment 414 is performed prior to or following a post-exposure bake. In an embodiment, the radical species treatment 414 is performed at temperature in the range of 60-400 degrees Celsius, at a pressure of 50 mTorr to 20 Torr, and for a duration in the range of 10 seconds to 60 minutes. In an embodiment, the radical species treatment 414 is performed using an inductively coupled plasma (ICP) source, a remote plasma source, or a microwave plasma source.

In an embodiment, the metal-oxide photoresist 406 is a positive tone photoresist. In another embodiment, the metal-oxide photoresist 406 is a negative tone photoresist. In an embodiment, developing the exposed metal-oxide photoresist 406A includes removing the non-exposed regions 412, as is depicted. In another embodiment, however, developing the exposed metal-oxide photoresist 406A includes removing the exposed regions 410.

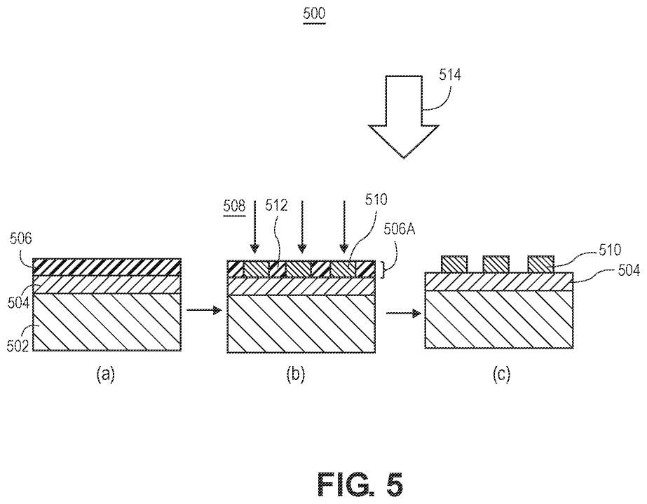

As a third exemplary process flow, FIG. 5 illustrates cross-sectional views representing various operations in a method of patterning a photo-resist layer, in accordance with an embodiment of the present disclosure.

Referring to FIG. 5, a method 500 of patterning a metal-oxide photoresist, such as a Sn-based photoresist, includes (a) depositing the metal-oxide photoresist 506 over a substrate 502 (with optional underlayer(s) and/or hardmask(s) 504 there between). In one embodiment, the underlayer(s) and/or hardmask(s) 504 are one or more layers such as a spin-on or CVD SiOC layer, a spin-on CVD carbon layer, a CVD amorphous silicon layer, a CVD SiON layer, and/or a spin-on or CVD or ALD metal oxide layer. In one embodiment, the photoresist 506 is a spin-on organic resist, a spin on metal oxide resist, or a CVD metal oxide resist.

The method also includes (b) exposing the metal-oxide photoresist with an extreme ultra-violet (EUV) exposure 508 to form exposed regions 510 and non-exposed regions 512. The method also includes (c) developing the exposed metal-oxide photoresist 506A. It is to be appreciated that the remaining mask (e.g., exposed regions 510) can be used as an etch mask to pattern underlying layers.

Referring again to FIG. 5, in accordance with an embodiment of the present disclosure, both a thermal treatment and a radical species treatment 514 of the metal-oxide photoresist is performed. In one such embodiment, the thermal treatment and the radical species treatment 514 are performed at one or more of the following stages: (a) following deposition but prior to exposure, (b) following exposure but prior to development, and/or (c) following development and prior to using the developed photoresist as an etch mask. Regarding (b), in one embodiment, the thermal treatment and the radical species treatment 514 are performed prior to or following a post-exposure bake. In one embodiment, the thermal treatment is performed prior to the radical species treatment. In another embodiment, the radical species treatment is performed prior to the thermal treatment.

In an embodiment, the thermal treatment portion of the thermal treatment and the radical species treatment 514 is performed at temperature in the range of 60-400 degrees Celsius, at a pressure of 1 Torr to 760 Torr, and for a duration in the range of 10 seconds to 60 minutes. In an embodiment, the radical species treatment portion of the thermal treatment and the radical species treatment 514 is performed at temperature in the range of 60-400 degrees Celsius, at a pressure of 50 Torr to 300 Torr, and for a duration in the range of 10 seconds to 10 minutes. In an embodiment, the radical species treatment portion of the thermal treatment and the radical species treatment 514 is performed using an inductively coupled plasma (ICP) source, a remote plasma source, or a microwave plasma source.

In an embodiment, the metal-oxide photoresist 506 is a positive tone photoresist. In another embodiment, the metal-oxide photoresist 506 is a negative tone photoresist. In an embodiment, developing the exposed metal-oxide photoresist 506A includes removing the non-exposed regions 512, as is depicted. In another embodiment, however, developing the exposed metal-oxide photoresist 506A includes removing the exposed regions 510.

In accordance with an embodiment of the present disclosure, a positive tone or negative tone photoresist is fabricated by using a particular type of R group in the metal precursor or plasma assisted deposition methods. It is to be appreciated that the lithography industry is typically used to dealing with positive tone PRs, however almost all of the novel metal-oxo PRs are negative tone PRs. Embodiments described herein can be implemented for both positive tone PRs and negative tone PRs.

In another aspect, for an exposure environment, when the photoresist is exposed by an energy source (e.g., EUV) the exposure chamber (environment) can be oxygen-containing or inert. In one embodiment, exposure is under vacuum with an oxygen source such as O₂, H₂O, CO₂, CO, NO₂, or NO. A repetition of EUV exposure and then oxygen exposure can be, in one embodiment, between 1 and 100 times.

Regarding deposition of a metal-oxide photoresist, in accordance with an embodiment of the present disclosure, a wet or spin-on approach can be used. In another embodiment, a dry deposition approach is used. In a first such dry deposition approach, a chemical vapor deposition (CVD) method for forming a positive tone or negative tone photoresist includes: (A) One or more metal precursors and one or more oxidants are vaporized to a vacuum chamber where a substrate wafer is maintained at a pre-determined substrate temperature. Substrate temperature can vary from 0 C to 500 C. When the precursors/oxidants are vaporized to the chamber, they can be diluted with inert gases such as Ar, N₂, He. Due to the reactivity of the precursor and oxidant, metal-oxo film is deposited on the wafer. Vaporization to the chamber can be performed by all precursors simultaneously or alternative pulsing of metal precursor(s) and oxidant(s). This process can be described as thermal CVD. (B) Plasma can be turned on during this process as well, and then the process can be described as plasma enhanced (PE)-CVD. Examples of plasma sources are CCP, ICP, remote plasma, microwave plasma. (C) Photoresist film deposition can be performed by thermal deposition followed by plasma treatment. In this case, film is deposited thermally and then a plasma treatment operation is performed. Plasma treatment may involve plasma from inert gasses such as Ar, N₂, He or those gasses can be mixed with O₂, CO₂, CO, NO, NO₂, H₂O. The processes can be carried out as in cyclic fashion; thermal deposition followed by plasma treatment and repeat this cycle or complete the deposition part and then do one plasma treatment (post treatment). PECVD followed by plasma treatment is also possible. In either case, in an embodiment, a post anneal in an oxygen-containing environment is performed. In one embodiment, the post anneal is performed using ozone (O₃) as an oxygen source gas, at a temperature in the range of 25-250 degrees Celsius, at a pressure less than 200 torr.

In a second approach, in accordance with an embodiment of the present disclosure, an atomic layer deposition (ALD) method for forming a positive tone or negative tone photoresist includes: (A) A metal precursor from is vaporized to an vacuum chamber where a substrate wafer is maintained at a pre-determined substrate temperature. Substrate temperature can vary from 0 to 500 C. Then, an inter gas purge is provided to remove by-products and excess metal precursor. Then, one or more oxidant is vaporized to the chamber. The oxidant(s) react with surface absorbed metal precursor. Then, an inert gas purge is applied to remove the by-products and unreacted oxidant. This cycle can be repeated to achieve the desired thickness. When the precursor or oxidant is vaporized to the chamber, it can be diluted with inert gases such as Ar, N₂, He. This process can be described as thermal ALD. Using this method more than one metal can be incorporated into the film by incorporating additional metal precursor pulses to a ALD cycle. Also, a different oxidant can be pulsed after the first oxidant. (B) A plasma can be turned on during the oxidant pulse and then the process can be described as PE-ALD. (C) Also, the deposition can be performed by thermal ALD followed by plasma treatment. In this case, film is deposited by thermally and then a plasma treatment operation is carried out. Plasma treatment may involve plasma from inert gasses such as Ar, N₂, He or those gasses can be mixed with O₂, CO₂, CO, NO, NO₂, H₂O. The processes can be performed as in cyclic fashion; X number of thermal ALD cycles (X=1-5000) followed by plasma treatment and repeat the whole cycle for desired number of times, or complete the deposition part and then do one plasma treatment. PE-ALD followed by plasma treatment is also possible. In either case, in an embodiment, a post anneal in an oxygen-containing environment is performed. In one embodiment, the post anneal is performed using ozone (O₃) as an oxygen source gas, at a temperature in the range of 25-250 degrees Celsius, at a pressure less than 200 torr.

In a third approach, in accordance with an embodiment of the present disclosure, an atomic layer deposition (ALD) or chemical vapor deposition (CVD) method for forming a positive tone or negative tone photoresist includes providing a composition gradient throughout the film. As an example, the first few nanometers of the film have a different composition than the rest of the film. The main portion of the film can be optimized for dose, but target a different composition close to the interface layer to change adhesion, sensitivity to EUV photons, sensitivity to develop chemistry in order to improve post lithography profile control (especially scumming) as well as defectivity and resist collapse/lift off. The gradation might be optimized for pattern type, for example pillars needing improved adhesion vs line/space patterns being able to lower adhesion for improvements in dose.

In an embodiment, a vacuum deposition process relies on chemical reactions between a metal precursor and an oxidant. The metal precursor and the oxidant are vaporized to a vacuum chamber. In some embodiments, the metal precursor and the oxidant are provided to the vacuum chamber together. In other embodiments, the metal precursor and the oxidant are provided to the vacuum chamber with alternating pulses. After a metal-oxo positive or negative tone photoresist film with a desired thickness is formed, the process may be halted. In an embodiment, an optional plasma treatment operation may be executed after a metal-oxo positive or negative tone photoresist film with a desired thickness is formed.

In an embodiment, a cycle including a pulse of the metal precursor vapor and a pulse of the oxidant vapor may be repeated a plurality of times to provide a metal-oxo positive or negative tone photoresist film with a desired thickness. In an embodiment, the order of the cycle may be switched. For example, the oxidant vapor may be pulsed first and the metal precursor vapor may be pulsed second. In an embodiment, a pulse duration of the metal precursor vapor may be substantially similar to a pulse duration of the oxidant vapor. In other embodiments, the pulse duration of the metal precursor vapor may be different than the pulse duration of the oxidant vapor. In an embodiment, the pulse durations may be between 0 seconds and 1 minute. In a particular embodiment, the pulse durations may be between 1 second and 5 seconds. In an embodiment, each iteration of the cycle uses the same processing gasses. In other embodiments, the processing gasses may be changed between cycles. For example, a first cycle may utilize a first metal precursor vapor, and a second cycle may utilize a second metal precursor vapor. Subsequent cycles may continue alternating between the first metal precursor vapor and the second metal precursor vapor. In an embodiment, multiple oxidant vapors may be alternated between cycles in a similar fashion. In an embodiment, an optional plasma treatment of operation may be executed after every cycle. That is, each cycle may include a pulse of metal precursor vapor, a pulse of oxidant vapor, and a plasma treatment. In an alternate embodiment, an optional plasma treatment of operation may be executed after a plurality of cycles. In yet another embodiment, an optional plasma treatment operation may be executed after the completion of all cycles (i.e., as a post treatment).

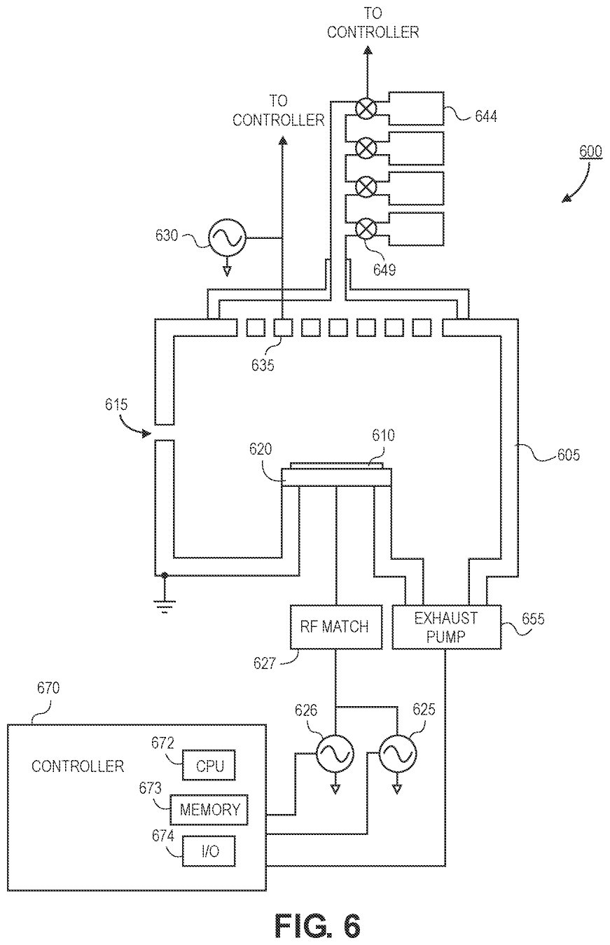

In an embodiment, a vacuum chamber utilized in a dry deposition process and/or a treatment process is any suitable chamber capable of providing a sub-atmospheric pressure. In an embodiment, the vacuum chamber may include temperature control features for controlling chamber wall temperatures and/or for controlling a temperature of the substrate. In an embodiment, the vacuum chamber may also include features for providing a plasma within the chamber. A more detailed description of a suitable vacuum chamber is provided below with respect to FIG. 6. FIG. 6 is a schematic of a vacuum chamber configured to perform a dry deposition of a metal-oxo photoresist and/or thermal treatment or radical species treatment of a photoresist, in accordance with an embodiment of the present disclosure.

Vacuum chamber 600 includes a grounded chamber 605. A substrate 610 is loaded through an opening 615 and clamped to a temperature controlled chuck 620. In an embodiment, the substrate 610 may be temperature controlled during a dry deposition or treatment process. For example, the temperature of the substrate 610 may be between approximately −40 degrees Celsius to 200 degrees Celsius. In a particular embodiment, the substrate 610 may be held to a temperature between room temperature and 150° C.

Process gases, are supplied from gas sources 644 through respective mass flow controllers 649 to the interior of the chamber 605. In certain embodiments, a gas distribution plate 635 provides for distribution of process gases 644, such as a ligand and an inert gas. Chamber 605 is evacuated via an exhaust pump 655. In one embodiment, one or more of the process gases are contained/stored in one or more ampoules. In one embodiment, the dry deposition process is a chemical vapor condensation process, and the one or more ampoules are maintained at a temperature above the substrate temperature, such as at a temperature 25 degrees Celsius or greater than the substrate temperature.

When RF power is applied during processing of a substrate 610, a plasma is formed in chamber processing region over substrate 610. Bias power RF generator 625 is coupled to the temperature controlled chuck 620. Bias power RF generator 625 provides bias power, if desired, to energize the plasma. Bias power RF generator 625 may have a low frequency between about 2 MHz to 60 MHz for example, and in a particular embodiment, is in the 13.56 MHz band. In certain embodiments, the vacuum chamber 600 includes a third bias power RF generator 626 at a frequency at about the 2 MHz band which is connected to the same RF match 627 as bias power RF generator 625. Source power RF generator 630 is coupled through a match (not depicted) to a plasma generating element (e.g., gas distribution plate 635) to provide a source power to energize the plasma. Source RF generator 630 may have a frequency between 100 and 180 MHz, for example, and in a particular embodiment, is in the 162 MHz band. Because substrate diameters have progressed over time, from 150 mm, 200 mm, 300 mm, etc., it is common in the art to normalize the source and bias power of a plasma etch system to the substrate area.

The vacuum chamber 600 is controlled by controller 670. The controller 670 may include a CPU 672, a memory 673, and an I/O interface 674. The CPU 672 may execute processing operations within the vacuum chamber 600 in accordance with instructions stored in the memory 673. For example, one or more processes such as processes 120 and 440 described above may be executed in the vacuum chamber by the controller 670.

In another aspect, embodiments disclosed herein include a processing tool that includes an architecture that is particularly suitable for optimizing dry deposition and/or thermal treatment or radical species treatment of a photoresist. For example, the processing tool may include a pedestal for supporting a wafer that is temperature controlled. In some embodiments, a temperature of the pedestal may be maintained between approximately −40° C. and approximately 300° C. Additionally, an edge purge flow and shadow ring may be provided around a perimeter of the column on which the substrate is supported. The edge purge flow and shadow ring prevent the positive or negative tone metal-oxide photoresist from depositing along the edge or backside of the wafer. In an embodiment, the pedestal may also provide any desired chucking architecture, such as, but not limited to vacuum chucking, monopolar chucking, or bipolar chucking, depending on the operating regime of the processing tool.

In some embodiments, the processing tool may be suitable for deposition processes without a plasma. Alternatively, the processing tool may include a plasma source to enable plasma enhanced operations. Furthermore, while embodiments disclosed herein are particularly suitable for the deposition of metal-oxo positive or negative tone photoresists for EUV patterning, it is to be appreciated that embodiments are not limited to such configurations. For example, the processing tools described herein may be suitable for depositing any positive or negative tone photoresist material for any regime of lithography.

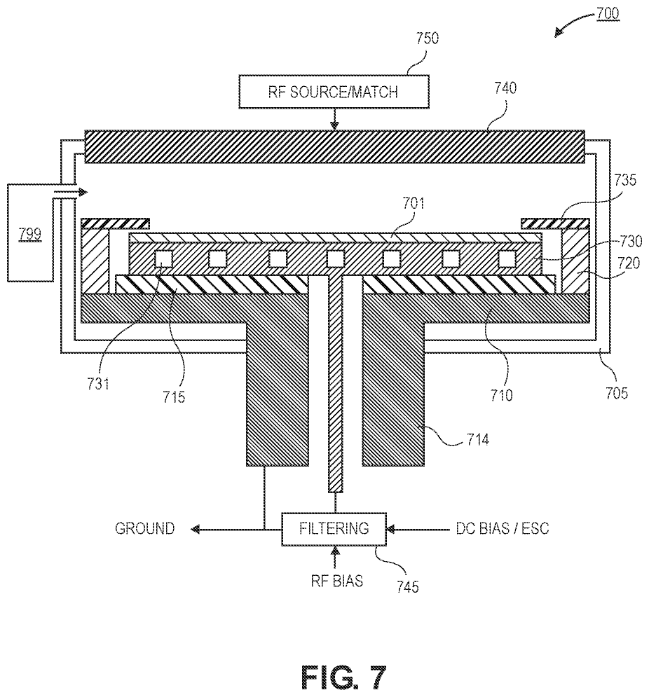

Referring now to FIG. 7, a cross-sectional illustration of a processing tool 700 is shown, in accordance with an embodiment. In an embodiment, the processing tool 700 may include a chamber 705. The chamber 705 may be any suitable chamber capable of supporting a sub-atmospheric pressure (e.g., a vacuum pressure). In an embodiment, an exhaust (not shown) that includes a vacuum pump may be coupled to the chamber 705 to provide a sub-atmospheric pressure. In an embodiment, a lid may seal the chamber 705. For example, the lid may include a showerhead assembly 740 or the like. The showerhead assembly 740 may include fluidic pathways to enable processing gasses and/or inert gasses to be flown into the chamber 705. In some embodiments where the processing tool 700 is suitable for plasma enhanced operation, the showerhead assembly 740 may be electrically coupled to an RF source and matching circuitry 750. In yet another embodiment, the tool 700 may be configured in an RF bottom fed architecture. That is, the pedestal 730 is connected to an RF source, and the showerhead assembly 740 is grounded. In such an embodiment, the filtering circuitry may still be connected to the pedestal. In one embodiment, a precursor gas is stored in an ampoule 799.

In an embodiment, a displaceable column for supporting a wafer 701 is provided in the chamber 705. In an embodiment, the wafer 701 may be any substrate on which a positive or negative tone metal-oxide photoresist material is deposited. For example, the wafer 701 may be a 300 mm wafer or a 450 mm wafer, though other wafer diameters may also be used. Additionally, the wafer 701 may be replaced with a substrate that has a non-circular shape in some embodiments. The displaceable column may include a pillar 714 that extends out of the chamber 705. The pillar 714 may have a port to provide electrical and fluidic paths to various components of the column from outside the chamber 705.

In an embodiment, the column may include a baseplate 710. The baseplate 710 may be grounded. As will be described in greater detail below, the baseplate 710 May include fluidic channels to allow for the flow of an inert gas to provide an edge purge flow.

In an embodiment, an insulating layer 715 is disposed over the baseplate 710. The insulating layer 715 may be any suitable dielectric material. For example, the insulating layer 715 may be a ceramic plate or the like. In an embodiment, a pedestal 730 is disposed over the insulating layer 715. The pedestal 730 may include a single material or the pedestal 730 may be formed from different materials. In an embodiment, the pedestal 730 may utilize any suitable chucking system to secure the wafer 701. For example, the pedestal 730 may be a vacuum chuck or a monopolar chuck. In embodiments where a plasma is not generated in the chamber 705, the pedestal 730 may utilize a bipolar chucking architecture.

The pedestal 730 may include a plurality of cooling channels 731. The cooling channels 731 may be connected to a fluid input and a fluid output (not shown) that pass through the pillar 714. In an embodiment, the cooling channels 731 allow for the temperature of the wafer 701 to be controlled during operation of the processing tool 700. For example, the cooling channels 731 may allow for the temperature of the wafer 701 to be controlled to between approximately −40° C. and approximately 300° C. In an embodiment, the pedestal 730 connects to the ground through filtering circuitry 745, which enables DC and/or RF biasing of the pedestal with respect to the ground.

In an embodiment, an edge ring 720 surrounds a perimeter of the insulating layer 715 and the pedestal 730. The edge ring 720 may be a dielectric material, such as a ceramic. In an embodiment, the edge ring 720 is supported by the base plate 710. The edge ring 720 may support a shadow ring 735. The shadow ring 735 has an interior diameter that is smaller than a diameter of the wafer 701. As such, the shadow ring 735 blocks the positive or negative tone metal-oxide photoresist from being deposited onto a portion of the outer edge of the wafer 701. A gap is provided between the shadow ring 735 and the wafer 701. The gap prevents the shadow ring 735 from contacting the wafer 701, and provides an outlet for the edge purge flow that will be described in greater detail below. In an embodiment, a dual channel showerhead can be used for a positive or negative tone metal-oxide photoresist fabrication process.

While the shadow ring 735 provides some protection of the top surface and edge of the wafer 701, processing gasses may flow/diffuse down along a path between the edge ring 720 and the wafer 701. As such, embodiments disclosed herein may include a fluidic path between the edge ring 720 and the pedestal 730 to enable an edge purge flow. Providing an inert gas in the fluidic path increases the local pressure in the fluidic path and prevents processing gasses from reaching the edge of the wafer 701. Therefore, deposition of the positive or negative tone metal-oxide photoresist is prevented along the edge of the wafer 701.

It is to be appreciated that, in accordance with one or more embodiments described herein, a treatment chamber suitable for performing one or more embodiments described herein can include a substrate support (heated chuck or edge ring), a method of heating (lamp based or heater based), and radical species treatment using radical species generated using either a remote plasma source, or an inductively coupled plasma source or a microwave plasma source.

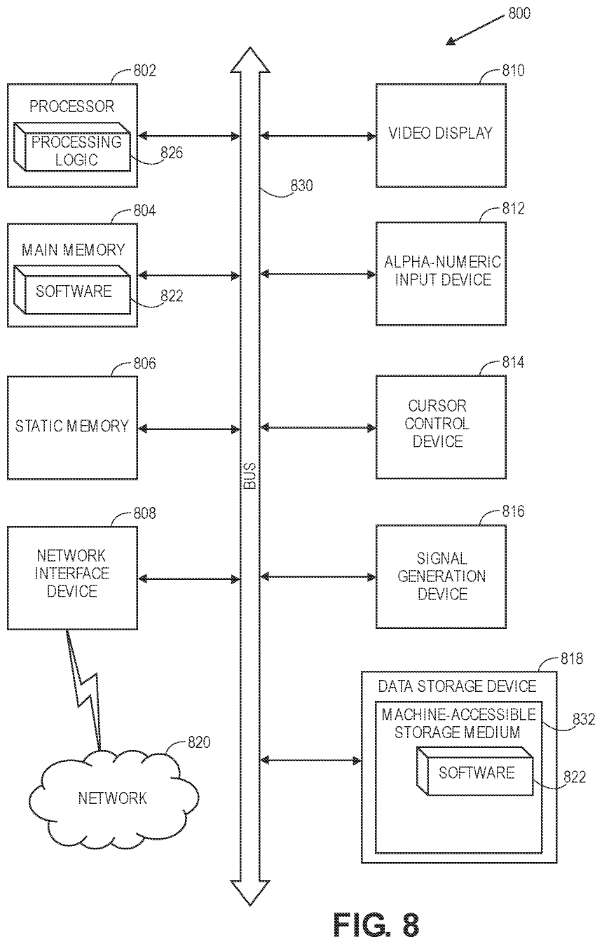

FIG. 8 illustrates a diagrammatic representation of a machine in the exemplary form of a computer system 800 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 800 includes a processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), MRAM, etc.), and a secondary memory 818 (e.g., a data storage device), which communicate with each other via a bus 830.

Processor 802 represents one or more general-purpose processing devices such as a microprocessor, central processing unit, or the like. More particularly, the processor 802 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 802 may also be one or more special-purpose processing devices such as an application specific integrated circuit (ASIC), a field programmable gate array (FPGA), a digital signal processor (DSP), network processor, or the like. Processor 802 is configured to execute the processing logic 826 for performing the operations described herein.

The computer system 800 may further include a network interface device 808. The computer system 800 also may include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium (or more specifically a computer-readable storage medium) 832 on which is stored one or more sets of instructions (e.g., software 822) embodying any one or more of the methodologies or functions described herein. The software 822 may also reside, completely or at least partially, within the main memory 804 and/or within the processor 802 during execution thereof by the computer system 800, the main memory 804 and the processor 802 also constituting machine-readable storage media. The software 822 may further be transmitted or received over a network 820 via the network interface device 808.

While the machine-accessible storage medium 832 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, and optical and magnetic media.

In accordance with an embodiment of the present disclosure, a machine-accessible storage medium has instructions stored thereon which cause a data processing system to perform a method of forming and/or treating a positive or negative tone metal-oxide photoresist layer.

Thus, methods for thermal treatment or radical species treatment of a photoresist of a positive tone or negative tone photoresist have been disclosed.

What is claimed is:

1. A method of patterning a metal-oxide photoresist, comprising:
depositing the metal-oxide photoresist over a substrate;
exposing the metal-oxide photoresist with an extreme ultra-violet (EUV) exposure to form exposed regions and non-exposed regions;
developing the exposed metal-oxide photoresist; and
performing a thermal treatment of the metal-oxide photoresist.

2. The method of claim 1, wherein the thermal treatment of the metal-oxide photoresist is performed following the depositing but prior to the exposing of the metal-oxide photoresist.

3. The method of claim 1, wherein the thermal treatment of the metal-oxide photoresist is performed following the exposing but prior to the developing of the metal-oxide photoresist.

4. The method of claim 1, wherein the thermal treatment of the metal-oxide photoresist is performed following the developing of the metal-oxide photoresist.

5. The method of claim 1, wherein the thermal treatment is performed at temperature in the range of 60-400 degrees Celsius, at a pressure of 1 Torr to 760 Torr, for a duration in the range of 10 seconds to 10 minutes, and using one or a mixture of gases selected from the group consisting of N₂, H₂, O₂, NH₃, Ar and He.

6. The method of claim 1, wherein the metal-oxide photoresist is a positive tone photoresist.

7. The method of claim 1, wherein the metal-oxide photoresist is a negative tone photoresist.

8. A method of patterning a metal-oxide photoresist, comprising:
depositing the metal-oxide photoresist over a substrate;
exposing the metal-oxide photoresist with an extreme ultra-violet (EUV) exposure to form exposed regions and non-exposed regions;
developing the exposed metal-oxide photoresist; and
performing a radical species treatment of the metal-oxide photoresist.

9. The method of claim 8, wherein the radical species treatment of the metal-oxide photoresist is performed following the depositing but prior to the exposing of the metal-oxide photoresist.

10. The method of claim 8, wherein the radical species treatment of the metal-oxide photoresist is performed following the exposing but prior to the developing of the metal-oxide photoresist.

11. The method of claim 8, wherein the radical species treatment of the metal-oxide photoresist is performed following the developing of the metal-oxide photoresist.

12. The method of claim 8, wherein the radical species treatment is performed at temperature in the range of 60-400 degrees Celsius, at a pressure of 50 mTorr to 20 Torr, for a duration in the range of 10 seconds to 10 minutes, and using one or a mixture of gases selected from the group consisting of N₂, H₂, O₂, NH₃, Ar and He.

13. The method of claim 8, wherein the radical species treatment is performed using an inductively coupled plasma (ICP) source, a remote plasma source, or a microwave plasma source.

14. The method of claim 8, wherein the metal-oxide photoresist is a positive tone photoresist.

15. The method of claim 8, wherein the metal-oxide photoresist is a negative tone photoresist.

16. A method of patterning a metal-oxide photoresist, comprising:
depositing the metal-oxide photoresist over a substrate;
exposing the metal-oxide photoresist with an extreme ultra-violet (EUV) exposure to form exposed regions and non-exposed regions;
developing the exposed metal-oxide photoresist;
performing a thermal treatment of the metal-oxide photoresist; and
performing a radical species treatment of the metal-oxide photoresist.

17. The method of claim 16, wherein the thermal treatment is performed prior to the radical species treatment.

18. The method of claim 16, wherein the radical species treatment is performed prior to the thermal treatment.

19. The method of claim 16, wherein the thermal treatment is performed at temperature in the range of 60-400 degrees Celsius, at a pressure of 1 Torr to 760 Torr, and for a duration in the range of 10 seconds to 60 minutes.

20. The method of claim 16, wherein the radical species treatment is performed at temperature in the range of 60-400 degrees Celsius, at a pressure of 50 mTorr to 20 Torr, and for a duration in the range of 10 seconds to 10 minutes, and wherein the radical species treatment is performed using an inductively coupled plasma (ICP) source, a remote plasma source, or a microwave plasma source.
